(19) United States
(12) Patent Application Publication
(10) Pub. No.: US 2007/0092982 A1
(43) Pub. Date: Apr. 26, 2007

(54) Method of fabricating flexible micro-capacitive ultrasonic transducer by the use of imprinting and transfer printing techniques

(75) Inventor: Chin-Chung Nien, Hsinchu City (TW)

Correspondence Address: BRUCE H. TROXELL, SUITE 1404, 5205 LEESBURG PIKE, FALLS CHURCH, VA, 22041, US

(73) Assignee: Industrial Technolgy Research Institute

(21) Appl. No.: 11/269,719

(22) Filed: Nov. 9, 2005

(30) Foreign Application Priority Data
Oct. 21, 2005 (TW) 094136905

(51) Int. Cl. H01L 21/00

(52) U.S. Cl. 438/50

(57) ABSTRACT

A method of fabricating flexible micro-capacitive ultrasonic transducer by the use of imprinting and transfer printing techniques is disclosed, which mainly comprises the steps of: forming oscillation cavities by imprinting; forming fixed electrodes by transfer printing; forming oscillation films by transfer printing; forming driving electrodes by transfer printing; and so on. In detail, the method of the invention first forming arrays of oscillation cavities and fixed electrodes on a polymer-based substrate simultaneously by the use of a patterned imprint mold having fixed electrodes of transfer printing attached thereon, and then, using the imprint mold coated with a specific material of oscillation film to form the same on the imprinted substrate corresponding to the array of oscillation cavities by transfer printing, and thereafter, using the imprint mold having patterned array of driving electrodes attached thereon to form a layer of driving electrodes on the oscillation film corresponding to the array of fixed electrodes by transfer printing; wherein each driving electrode is connected to interconnects before being patterned and attached on the imprint mold so that the driving electrodes and the interconnects corresponding thereto can be formed on the oscillation film by transfer printing simultaneously. In a preferred embodiment, via holes are formed on the polymer-based substrate at positions corresponding to that of the fixed electrodes in advance so that, at a later step, interconnects for fixed electrodes can be formed by performing a metal depositing method upon the back of the substrate masked by a mask with interconnect patterns.

### FIELD OF THE INVENTION

The present invention relates to a method of fabricating flexible micro-capacitive ultrasonic transducer by the use of imprinting and transfer printing techniques, and more particularly, to a simple, low cost fabrication process of micro-capacitive ultrasonic transducer, which is adapted for mass production and is capable of forming arrays of nano-scaled oscillation cavities on a flexible polymer-based substrate of a micro-capacitive ultrasonic transducer by the use of imprinting and transfer printing techniques.

### BACKGROUND OF THE INVENTION

Increasing interest has been focused, in the last decade, on development of sensitive and efficient ultrasonic transducers, because of the growing demand from the wide field of ultrasound applications. Ultrasound is used for detection, characterization and sizing of defects in materials without contact and without causing damage (non-destructive tests).

Currently, the transducers that are being used are piezoelectric devices made of piezoelectric ceramics, but their drawbacks are well-known and listed as following:
(1) The cost of fabricating a piezoelectric transducer is relatively high in comparison.
(2) The deformation of crystal lattices in the piezoelectric crystal of a piezoelectric transducer will cause the bandwidth and the acoustic pressure generated by the piezoelectric transducer to decrease accordingly.
(3) The acoustic impedance of the piezoelectric ceramic used in a piezoelectric transducer is much larger than that of air or liquid media and, as a consequence, the mismatching will cause the acoustic signals to be reflected in great amount, and thus the efficiency of the piezoelectric transducer is reduced while it is being used in a non-destructive test.

Recently, micro-capacitive ultrasonic transducers have been developed as an attractive alternative to piezoelectric ones, which is usually a micro capacitive device having arrays of oscillation cavities formed on the sacrificial layer of a silicon wafer used as substrate by a means of wet etching. Please refer to FIG. 1A to FIG. 1C, which are schematic diagrams depicting a prior-art fabrication method of micro-capacitive ultrasonic transducer as disclosed in U.S. Pat. No. 6,004,832, entitled “METHOD OF FABRICATING AN ELECTROSTATIC ULTRASONIC TRANSDUCER”. The process starts with providing a silicon wafer 91 served as the substrate. The next steps are to grow an oxide layer 92 followed by the deposition of an oscillation film layer 93, and then two conductive layers 94 are respectively formed upon the both sides of the wafer 91. The resulting structure is shown in FIG. 1A. In FIG. 1B, an array of holes 96 are formed on the resulting structure of FIG. 1A, that each penetrates the oscillation film layer 93 and top conductive layer 94 for providing access to the oxide layer 92 acted as a sacrificial layer. As seen in FIG. 1C, the sacrificial layer 92 is then etched away by a suitable etchant through the access provided by the holes 96, such that column-like oscillation cavities 97 respectively centering each hole 96 can be formed while the size thereof is controlled by the etch time, which is illustrated in FIG. 2. However, the aforesaid fabrication method has shortcomings as following:
(1) The formation of oscillation cavities is heavily rely on past experience, since the variables of the prior-art fabrication method, such as the concentration of the etchant, the temperature, the density and the particle moving speed of the sacrificial layer, etc., can all have affect on the size of the oscillation cavities 97 formed thereby such that the characteristics of the product of the fabrication process is varied accordingly and thus the yield of the product is affected adversely.
(2) The etching process used by the prior art can not accurately control the formation of the oscillation cavities 97, so that the size of different cavities 97 formed thereby are varies and thus the transducer with cavities of various size will have unexpected resonant characteristic.
(3) The prior-art method requires several etching processes, each using different etchant corresponding to its target layer, whereas a poorly selected etchant and etching time thereof can cause an etching process to over-etch or etch a layer where it is not the target layer, and therefore, the resulting transducer might not be able to have efficiency as expected.
(4) Since the filling of etchant and the draining of by-product in the etching of oscillation cavities are only realized through the holes 96, the oscillation cavities formed thereby are contaminated and not east to clean, and further the residue resided therein can adversely affect the resulting transducer.
(5) Since prior-art fabrication methods adopt rigid substrate for forming cavities, electrodes and interconnects thereon, they are not applicable to the rising industries of biomedical testing and nano-testing, which require mass flexible micro-capacitive ultrasonic transducer.

### SUMMARY OF THE INVENTION

In view of the disadvantages of prior art, the primary object of the present invention is to provide a method of fabricating flexible micro-capacitive ultrasonic transducer by the use of imprinting and transfer printing techniques, which is a simple, low cost fabrication process of micro-capacitive ultrasonic transducer since once an required imprint mold is available, a micro-capacitive ultrasonic transducer can be fabricated by the techniques of imprinting and transfer printing that enables the fabrication method to be adapted for mass production with high yield, and accurately control the size of the nano-scaled oscillation cavities to be formed thereby.

It is another object of the invention to provide a method of fabricating flexible micro-capacitive ultrasonic transducer by the use of imprinting and transfer printing techniques, capable of forming arrays of nano-scaled oscillation cavities, electrodes and interconnects, etc., on a flexible polymer-based substrate, which enables the distance between the two electrodes of an oscillation cavity to be reduced comparing to that of prior-art method, and thus is capable of enhancing the sensitivity of a micro-capacitive ultrasonic transducer made thereby while enabling the realization of the making of flexible micro-capacitive ultrasonic transducer.

It is yet another object of the invention to provide a method of fabricating flexible micro-capacitive ultrasonic transducer by the use of imprinting and transfer printing techniques, which is capable of forming arrays of nano-scaled oscillation cavities at a preferred high precision so that not only the performance of the formed micro-capacitive ultrasonic transducer is enhanced, but also the application of the same is enlarged.

It is further another object of the invention to provide a method of fabricating flexible micro-capacitive ultrasonic transducer by the use of imprinting and transfer printing techniques, which can select materials suitable to be used as the substrate, the oscillation cavities, the electrodes and the interconnects of a micro-capacitive ultrasonic transducer while enabling the adhesion energies of the materials to be matched optimally.

To achieve the above objects, the present invention provides a method of fabricating flexible micro-capacitive ultrasonic transducer by the use of imprinting and transfer printing techniques, which comprises the steps of:
(a) providing an imprint mold with embossed patterns while attaching a corresponding fixed electrode upon the surface of each embossed patterns;
(b) providing a flexible polymer-base substrate;
(c) pressing the imprint mold on the substrate for enabling the embossed patterns to form oscillation cavities on the substrate by imprinting while transferring each fixed electrode inside it corresponding oscillation cavity by transfer printing;
(d) providing another imprint mold coated with a layer of dielectric polymer;
(e) transferring the layer of dielectric polymer onto the substrate imprinted with oscillation cavities by transfer printing so as to form an oscillation film on top of an oscillation cavity corresponding thereto;
(f) providing yet another imprint mold having metal driving electrodes attached thereon; and
(g) transferring each driving electrode onto the its corresponding oscillation film by transfer printing.

In a preferred embodiment of the invention, the imprint mold of step (f) further have interconnects of the driving electrodes attached thereon so that the driving electrodes and the interconnects thereof can be transferred simultaneously by the used of the referring imprint mold for transfer printing.

In another preferred embodiment of the invention, the means of imprint used can be selected from the group consisting of hot imprint, laser-assisted imprint and the like.

In a preferred aspect, the polymer-based substrate of imprinting and transfer printing used in the fabrication of a micro-capacitive ultrasonic transducer is a material selected with respect to best match a specific usage of the micro-capacitive ultrasonic transducer.

Moreover, to achieve the above objects, the present invention provides a method of fabricating flexible micro-capacitive ultrasonic transducer by the use of imprinting and transfer printing techniques, the method comprising the steps of:
(a) providing an imprint mold with embossed patterns while attaching a corresponding fixed electrode upon the surface of each embossed patterns;
(b) providing a flexible polymer-base substrate with array of via holes arranged thereon while enabling each via hole to align with the center of a corresponding fixed electrode;
(c) pressing the imprint mold on the substrate for enabling the embossed patterns to form oscillation cavities on the substrate by imprinting while transferring each fixed electrode inside it corresponding oscillation cavity at the position corresponding to the via hole thereof by transfer printing;
(d) providing another imprint mold coated with a layer of dielectric polymer;
(e) transferring the layer of dielectric polymer onto the substrate imprinted with oscillation cavities by transfer printing so as to form an oscillation film on top of an oscillation cavity corresponding thereto;
(f) providing yet another imprint mold having metal driving electrodes attached thereon;
(g) transferring each driving electrode onto the its corresponding oscillation film by transfer printing;
(h) providing a mask patterned with array of via holes and interconnects; and
(i) using the mask with array of via holes and interconnects to deposit and form interconnects of fixed electrodes on the back of the substrate by a metal depositing method adopted by a semiconductor process.

In a preferred embodiment of the invention, the means of imprinting used can be selected from the group consisting of hot imprint, laser-assisted imprint and the like.

In a preferred aspect, the polymer-based substrate of imprinting and transfer printing used in the fabrication of a micro-capacitive ultrasonic transducer is a material selected with respect to best match a specific usage of the micro-capacitive ultrasonic transducer.

Other aspects and advantages of the present invention will become apparent from the following detailed description, taken in conjunction with the accompanying drawings, illustrating by way of example the principles of the present invention.

### BRIEF DESCRIPTION OF THE DRAWINGS

FIG. 1A to FIG. 1C are schematic diagrams depicting steps of a method of fabricating a micro-capacitive ultrasonic transducer according to prior art.

FIG. 2 is a top view of an array of oscillation cavities according to prior art.

FIG. 3A to FIG. 3C are schematic diagrams depicting steps of a method of fabricating a micro-capacitive ultrasonic transducer according to a preferred embodiment of the present invention.

FIG. 4 is schematic diagram depicting a step of forming driving electrodes by transfer print according to the preferred embodiment of FIG. 3C.

FIG. 5A to FIG. 5D are depicting steps of a method of fabricating a micro-capacitive ultrasonic transducer according to another preferred embodiment of the present invention.

FIG. 6A to FIG. 6C are schematic diagrams showing oscillation cavities of different shapes being formed by imprinting according to the present invention.

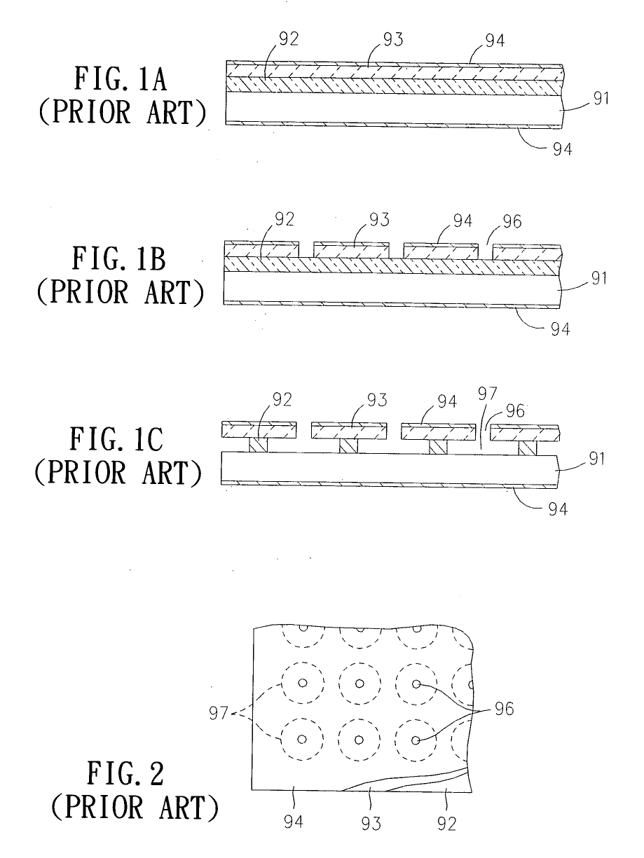

### DESCRIPTION OF THE PREFERRED EMBODIMENT

For your esteemed members of reviewing committee to further understand and recognize the fulfilled functions and structural characteristics of the invention, several preferable embodiments cooperating with detailed description are presented as the follows.

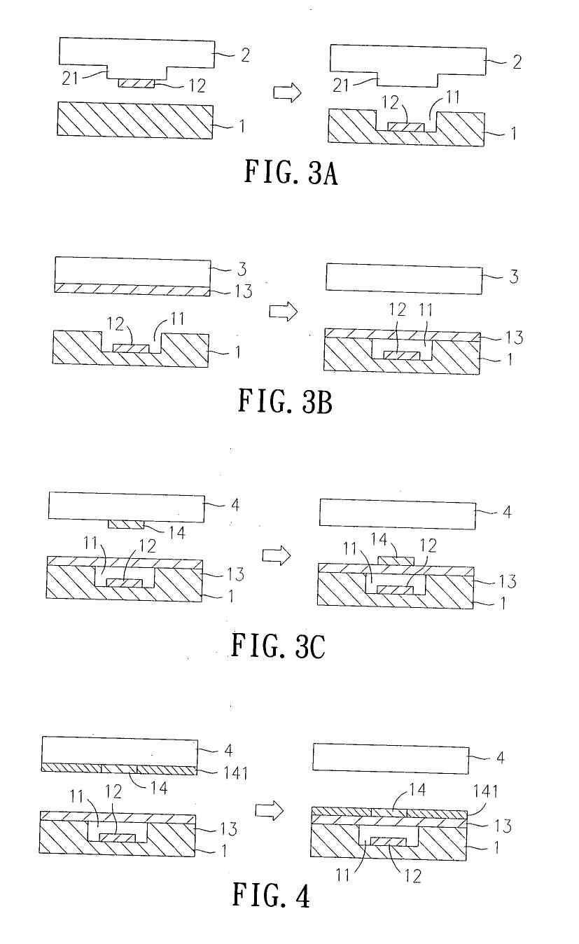

Please refer to FIG. 3A to FIG. 3C, which are schematic diagrams depicting steps of a method of fabricating a micro-capacitive ultrasonic transducer according to a preferred embodiment of the present invention. In the process of forming oscillation cavities 11 by imprinting and fixed electrodes 12 by transfer printing as shown in FIG. 3A, an imprint mold 2 with embossed patterns 21 is provided whereas the surface of each embossed patterns, is attached with a corresponding fixed electrode 12 of specific dimension, so that when the imprint mold 2 is pressed on a flexible substrate 1, the embossed patterns 21 can form corresponding oscillation cavities 11 on the flexible substrate 1 by imprinting while transferring each fixed electrode inside it corresponding oscillation cavity 11 by transfer printing. In the process of forming a layer of oscillation film 13 by transfer printing as shown in FIG. 3B, another imprint mold 3 coated with a layer of dielectric polymer 13 is provided which is capable of transferring the layer of dielectric polymer 13 onto the substrate 1 imprinted with oscillation cavities 11 by transfer printing for forming an oscillation film on top of an oscillation cavity 11 corresponding thereto. In the process of forming driving electrodes 14 by transfer printing as shown in FIG. 3C, further yet another imprint mold 4 having metal driving electrodes 14 attached thereon is provided which is capable of transferring each driving electrode 14 onto the its corresponding oscillation film 13 by transfer printing, and thus the process of fabricating a micro-capacitive ultrasonic transducer is completed.

In conclusion from the above description, the method of fabricating a micro-capacitive ultrasonic transducer according to the abovementioned preferred embodiment of the invention, comprises the steps of:
(a) providing an imprint mold 2 with embossed patterns 21 while attaching a corresponding fixed electrode 12 upon the surface of each embossed patterns 21;
(b) providing a flexible polymer-base substrate 1;
(c) pressing the imprint mold 2 on the substrate 1 for enabling the embossed patterns 21 to form oscillation cavities 11 on the substrate 1 by imprinting while transferring each fixed electrode 12 inside it corresponding oscillation cavity 11 by transfer printing;
(d) providing another imprint mold 3 coated with a layer of dielectric polymer 13;
(e) transferring the layer of dielectric polymer 13 onto the substrate 1 imprinted with oscillation cavities 11 by transfer printing so as to form an oscillation film on top of an oscillation cavity 11 corresponding thereto;
(f) providing yet another imprint mold 4 having metal driving electrodes 14 attached thereon; and
(g) transferring each driving electrode 14 onto the its corresponding oscillation film 13 by transfer printing.

Please refer to FIG. 4, which is schematic diagram depicting a step of forming driving electrodes by transfer print according to the preferred embodiment of FIG. 3C. In FIG. 4, the imprint mold 4 further have interconnects 141 corresponding to the driving electrodes 14 attached thereon so that the driving electrodes 14 and the interconnects 141 thereof can be transferred onto the oscillation film 13 simultaneously by the used of the imprint mold 4 for transfer printing, and thus the posterior process of forming interconnects can be saved.

In principle, the step of imprinting and transfer printing disclosed above is realized by utilizing the fact that the adhesion energy of an object adhered to a material is different to that of the object adhered to another material. Take the process of FIG. 3A for example, since the adhesion energy between the fixed electrode 12 and the substrate I is larger than that between the imprint mold 2 and the substrate 1, the embossed patterns 21 of the imprint mold 2 can be separated from the substrate 1 after being used to form oscillation cavities 11 thereon by imprinting while the fixed electrodes 12 are detached from the imprint mold 2 and adhere themselves onto the inside of corresponding oscillation cavities 11. Similarly, in the process of forming a layer of oscillation film 13 by transfer printing shown in FIG. 3B, since the adhesion energy between the dielectric polymer 13 and the substrate 1 is larger than that between the dielectric polymer 13 and the imprint mold 3, the dielectric polymer 13 can be detached from the imprint mold 3 and adhere themselves onto the substrate 1. Furthermore, in the process of forming driving electrodes 14 by transfer printing as shown in FIG. 3C, since the adhesion energy between the driving electrodes 14 and the oscillation film 13 is larger than that between the driving electrode 14 and the imprint mold 4, the driving electrodes 14 be detached from the imprint mold 4 and adhere themselves onto the corresponding oscillation films 13. In addition, in the process of forming driving electrodes 14 and the interconnects 141 thereof simultaneously shown in FIG. 4, since the adhesion energy between the driving electrodes 14 and the oscillation film 13 as well as that between the interconnects 141 and the oscillation film 13 is larger than that between the driving electrode 14 and the imprint mold 4 as well as that between the interconnects 141 and the imprint mold 4, the driving electrodes 14 along with corresponding interconnects can be detached from the imprint mold 4 and adhere themselves onto the corresponding oscillation films 13.

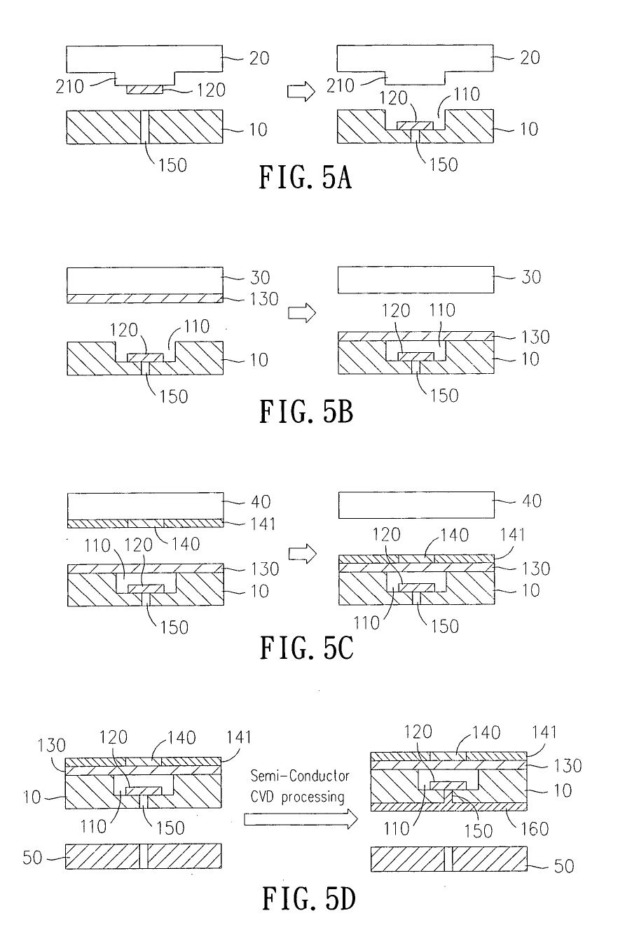

Please refer to FIG. SA to FIG. SD, which are depicting steps of a method of fabricating a micro-capacitive ultrasonic transducer according to another preferred embodiment of the present invention. The characteristic of the present embodiment is that the polymer-based substrate 10 is provided with an array of via holes 150 of metal disposition, which are previously formed for facilitating the formation of interconnects of fixed electrode 120. In the process of forming oscillation cavities II by imprinting and fixed electrodes 12 by transfer printing as shown in FIG. 5A, an imprint mold 20 with embossed patterns 210 is provided, whereas the surface of each embossed patterns 210 is attached with a corresponding fixed electrode 120 of specific dimension, so that when the imprint mold 20 is pressed on a flexible substrate 10 with array of via holes 150 arranged thereon and each aligned with the center of a corresponding fixed electrode 120, the embossed patterns 210 can form corresponding oscillation cavities 110 on the flexible substrate 10 by imprinting while transferring each fixed electrode inside it corresponding oscillation cavity 11 at the position corresponding to the via hole thereof 150 by transfer printing. In the process of forming a layer of oscillation film 130 by transfer printing as shown in FIG. 5B, another imprint mold 30 coated with a layer of dielectric polymer 130 is provided which is capable of transferring the layer of dielectric polymer 130 onto the substrate 10 imprinted with oscillation cavities 1 10 by transfer printing for forming an oscillation film 130 on top of an oscillation cavity 110 corresponding thereto. In the process of forming driving electrodes 140 by transfer printing as shown in FIG. 5C, further yet another imprint mold 40 having metal driving electrodes 140 attached thereon is provided and further the driving electrodes 14 are connected to the corresponding interconnects 141, which is capable of transferring each driving electrode 140 and the corresponding interconnects 141 onto the its corresponding oscillation film 130 by transfer printing. In the process of depositing interconnects of fixed electrodes as shown in FIG. 5D, a mask 50 patterned with array of via holes and interconnects is provided for using the mask 50 to deposit and form interconnects 160 of fixed electrodes 120 on the back of the substrate 10 by a metal depositing method adopted by a semiconductor process.

In conclusion from the above description, the method of fabricating a micro-capacitive ultrasonic transducer according to the abovementioned preferred embodiment of the invention, comprises the steps of:
(a) providing an imprint mold 20 with embossed patterns 210 while attaching a corresponding fixed electrode 120 upon the surface of each embossed patterns 210;
(b) providing a flexible polymer-base substrate 10 with array of via holes 150 arranged thereon while enabling each via hole 150 to align with the center of a corresponding fixed electrode 120;
(c) pressing the imprint mold 20 on the substrate 10 for enabling the embossed patterns 210 to form oscillation cavities 110 on the substrate 10 by imprinting while transferring each fixed electrode 120 inside it corresponding oscillation cavity 10 at the position corresponding to the via hole 150 thereof by transfer printing;
(d) providing another imprint mold 30 coated with a layer of dielectric polymer 130;
(e) transferring the layer of dielectric polymer 130 onto the substrate 10 imprinted with oscillation cavities 110 by transfer printing so as to form an oscillation film on top of an oscillation cavity 110 corresponding thereto;
(f) providing yet another imprint mold 40 having metal driving electrodes 140 attached thereon, the driving electrodes 140 being connected to corresponding interconnects 141;
(g) transferring each driving electrode 140 and corresponding interconnects onto the its corresponding oscillation film 130 by transfer printing;
(h) providing a mask 50 patterned with array of via holes and interconnects; and
(i) using the mask 50 with array of via holes and interconnects to deposit and form interconnects 160 of fixed electrodes 120 on the back of the substrate 10 by a metal depositing method adopted by a semiconductor process.

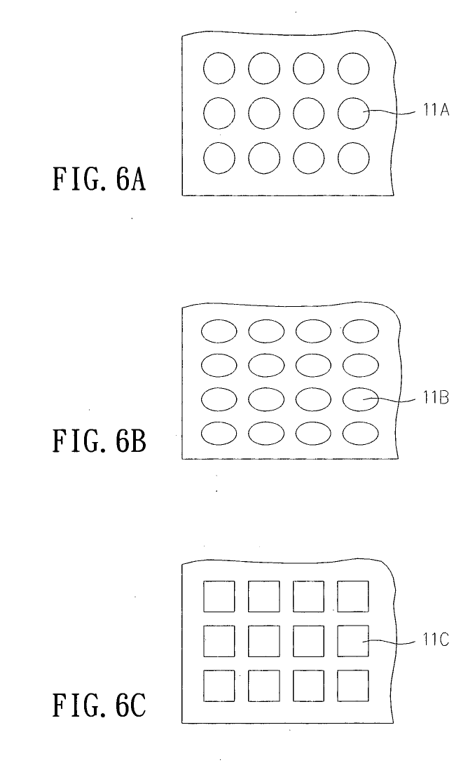

Moreover, it is noted that the oscillation cavities in the abovementioned two embodiments can be in any shape required by actual need as illustrated in FIG. 6A to FIG. 6C. That is, except for the traditional round shape cavity 11 A shown in FIG. 6A, the cavity can be an oval object 1B as shown in FIG. 6B or a rectangle object 11C as shown in FIG. 6C, or any other shaped object as require. It is noted that any specifications of the oscillation cavity, such as the shape, the size and the interval between any of the two cavities, etc., can be specified and altered during the making of the array of embossed patterns on the relating imprint mold. Furthermore, since the array of oscillation cavities is formed on a flexible polymer-based substrate by imprinting an imprint mold with array of embossed patterns thereon, the unity in both dimension and shape of each oscillation cavity can be ensured that it is beneficial to the resonant characteristic of the ultrasonic transducer.

To sum up, the method of fabricating flexible micro-capacitive ultrasonic transducer by the use of imprinting and transfer printing techniques according to the present invention has advantages as following:
(1) It facilitates the mass production of micro-capacitive ultrasonic transducer.
(2) The cost of micro-capacitive ultrasonic transducer fabrication is reduced.
(3) It adopts a flexible polymer as the substrate of the micro-capacitive ultrasonic transducer that makes the resulting ultrasonic transducer to be a flexible device.
(4) There are many polymers can be selected to be used for the imprinting and transfer printing whereas the selection criteria can be as that, for example, a bio-compatible material is selected so as to facilitate the use of the micro-capacitive ultrasonic transducer in a biomedical testing.
(5) It can enhance the sensitivity of the micro-capacitive ultrasonic transducer since the fabrication method can actually control the dimension of the oscillation cavities of the micro-capacitive ultrasonic transducer so that not only the distance between electrodes can be reduced, but also the unity of the oscillation cavities is enhanced.
(6) Since the fabrication method uses a polymer-based material for making the oscillation cavities, the Lamb wave effect caused by the use of traditional silicon-based material can be prevented.
(7) The holes required by the traditional fabrication method for filling in and draining etchant are not present in the method of the present invention, so that the contamination problem troubling the traditional fabrication method is prevented.
(8) The traditional fabrication process used two different materials for making the cavities and the oscillation film that cause the resulting micro-capacitive ultrasonic transducer to have unstable characteristics since the thermal expansion coefficients of the two materials are not the same, however, the fabrication process adopting the method of the present invention enables the possibility of using a same material to make the cavities and the oscillation film.
(9) The fabrication process adopting the method of the present invention enables the resulting micro-capacitive ultrasonic transducer to be nano-scaled so that the resulting nano-scaled micro-capacitive ultrasonic transducer can be more adapted to applications requiring micro devices.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

What is claimed is:

1. A method of fabricating flexible micro-capacitive ultrasonic transducer by the use of imprinting and transfer printing techniques, comprising the steps of:
(a) providing an imprint mold with embossed patterns while attaching a corresponding fixed electrode upon the surface of each embossed patterns;
(b) providing a flexible polymer-base substrate;
(c) pressing the imprint mold on the substrate for enabling the embossed patterns to form oscillation cavities on the substrate by imprinting while transferring each fixed electrode inside it corresponding oscillation cavity by transfer printing;
(d) providing another imprint mold coated with a layer of dielectric polymer;
(e) transferring the layer of dielectric polymer onto the substrate imprinted with oscillation cavities by transfer printing so as to form an oscillation film on top of an oscillation cavity corresponding thereto;
(f) providing yet another imprint mold having metal driving electrodes attached thereon; and
(g) transferring each driving electrode onto the its corresponding oscillation film by transfer printing.

2. The method of claim 1, wherein the imprint mold of step (f) further have interconnects corresponding to the driving electrodes attached thereon so that the driving electrodes and the interconnects thereof can be transferred onto the oscillation film simultaneously by the used of the referring imprint mold for transfer printing.

3. The method of claim 1, wherein the means of imprinting is selected from the group consisting of hot imprint, laser-assisted imprint and the like.

4. The method of claim 1, wherein the polymer-based substrate of imprinting and transfer printing used in the fabrication of a micro-capacitive ultrasonic transducer is a material selected with respect to best match a specific usage of the micro-capacitive ultrasonic transducer.

5. A method of fabricating flexible micro-capacitive ultrasonic transducer by the use of imprinting and transfer printing techniques, comprising the steps of:
(a) providing an imprint mold with embossed patterns while attaching a corresponding fixed electrode upon the surface of each embossed patterns;
(b) providing a flexible polymer-base substrate with array of via holes arranged thereon while enabling each via hole to align with the center of a corresponding fixed electrode;
(c) pressing the imprint mold on the substrate for enabling the embossed patterns to form oscillation cavities on the substrate by imprinting while transferring each fixed electrode inside it corresponding oscillation cavity at the position corresponding to the via hole thereof by transfer printing;
(d) providing another imprint mold coated with a layer of dielectric polymer;
(e) transferring the layer of dielectric polymer onto the substrate imprinted with oscillation cavities by transfer printing so as to form an oscillation film on top of an oscillation cavity corresponding thereto;
(f) providing yet another imprint mold having metal driving electrodes attached thereon;
(g) transferring each driving electrode onto the its corresponding oscillation film by transfer printing;
(h) providing a mask patterned with array of via holes and interconnects; and
(i) using the mask with array of via holes and interconnects to deposit and form interconnects of fixed electrodes on the back of the substrate by a metal depositing method adopted by a semiconductor process.

6. The method of claim 5, wherein the means of imprinting is selected from the group consisting of hot imprint, laser-assisted imprint and the like.

7. The method of claim 5, wherein the polymer-based substrate of imprinting and transfer printing used in the fabrication of a micro-capacitive ultrasonic transducer is a material selected with respect to best match a specific usage of the micro-capacitive ultrasonic transducer.
